(19) United States
(12) Patent Application Publication
(10) Pub. No.: US 2002/0135375 A1
(43) Pub. Date: Sep. 26, 2002

(54) Miniature christmas bulb extractor

(76) Inventor: William E. Suko, White Bear Lake, MN (US)

Correspondence Address: RIDER, BENNETT, EGAN & ARUNDEL, 333 SOUTH SEVENTH STREET, SUITE 2000, MINNEAPOLIS, MN, 55402, US

(21) Appl. No.: 09/814,432

(22) Filed: Mar. 21, 2001

(51) Int. Cl. G01R 31/00

(52) U.S. Cl. 324/414

(57) ABSTRACT

Apparatus for extracting and installing light bulbs from sockets, the light bulbs having a glass element, a base, and a circular collar between the glass element and the base, the base being insertable into a socket. The apparatus has a first handle having a first end and a second end and a groove in the second end to securely grip the base adjacent the collar of the light bulb; and a second handle having a first end and a second end and a groove at the second end. The second end of the first handle and the second end of the second handle are adjustably spaced from one another for receiving light bulb bases of varying size and are opposable for gripping the light bulb base, thereby allowing the operator to extract the light bulb and insert another light bulb into the socket.

### BACKGROUND OF THE INVENTION

The present invention pertains to a device for removing miniature Christmas light bulbs from their sockets.

Christmas lights are notorious, because of their limited seasonal use, for becoming defective between seasons. Christmas lights come in all sizes and are removably secured in sockets which are equally spaced on leads—more commonly known as a “string” of lights. The string generally has a plug at one end adapted to plug into a power source or into the opposite end of another string, whereby the string can be made longer.

Some bulbs are extremely tiny and difficult to hold without damaging the fragile connections, or pulling the glass portion loose from the base. The dexterity required to remove these bulbs from their sockets is quite high. This is especially true if the operator has arthritis or if the work is being done out of doors in characteristically cold Christmas-time temperatures. Lastly, one becomes frustrated after spending time struggling to remove a bulb from its socket, only to discover that one has positioned the bulb in a defective socket, or has damaged the bulb rendering it defective.

U.S. Pat. No. 5,369,363 discloses an implement for removing and installing and testing Christmas light bulbs. The bulb is removed from its socket by a bulb gripper in one end of the tool. However, the bulb gripper has fixed-size walls and therefore can only work with a particular size of bulb. Also, it appears from studying the specification that the device is at least partially inoperational, because using the device to install a bulb in a socket would probably cause the bulb gripper, whose walls are angled outwardly, to lose contact with the bulb as the bulb encounters the frictional resistance of the socket, making it quite difficult to install the bulb. The device is also unnecessarily complex.

There is a need for a simple, reliable, device for extracting Christmas light bulbs which is adaptable to a variety of bulb sizes and at the same time provides a secure grip on the bulb while the bulb is being installed in a socket.

The invention is particularly operable with type 2.5vSB midget push-in lamps. However, it could be used with any number of different lamp types.

A device of the present invention may be adapted from a fish hook eye cleaner as disclosed in U.S. Pat. No. 4,799,326.

### SUMMARY OF THE INVENTION

Apparatus for extracting and installing light bulbs from sockets, the light bulbs having a glass element, a base, and a circular collar between the glass element and the base, the base being insertable into a socket, the apparatus comprising:

a) a first handle having a first end and a second end and a groove in the second end adapted to securely grip the base adjacent the collar of the light bulb; and

b) a second handle having a first end and a second end and a groove at the second end, the second end of the first handle and the second end of the second handle being adjustably spaced from one another for receiving light bulb bases of varying size and being opposable for gripping the light bulb base therebetween, thereby allowing the operator to extract the light bulb and insert another light bulb into the socket.

A principal object and advantage of the present invention is that it can remove tiny Christmas light bulbs from sockets without damaging the bulb or the socket.

Another principal object and advantage of the present invention is that it is adjustable for bulbs of various sizes.

Another object and advantage of the present invention is that it provides a secure grip on a bulb, thereby allowing a bulb to be inserted into a socket.

Another object and advantage of the present invention is that it is simple and easy to manufacture.

### BRIEF DESCRIPTION OF THE DRAWINGS

FIG. 1 is a perspective view showing a light bulb and socket for use with the present invention.

FIG. 2 is a perspective view showing a first embodiment of the present invention.

FIGS. 3 and 4 are detailed perspective views of a first embodiment of the present invention.

FIGS. 5 and 6 are side elevational views of a second embodiment of the present invention.

FIG. 7 is an end view of the second embodiment of the present invention.

### DETAILED DESCRIPTION OF THE PREFERRED EMBODIMENT

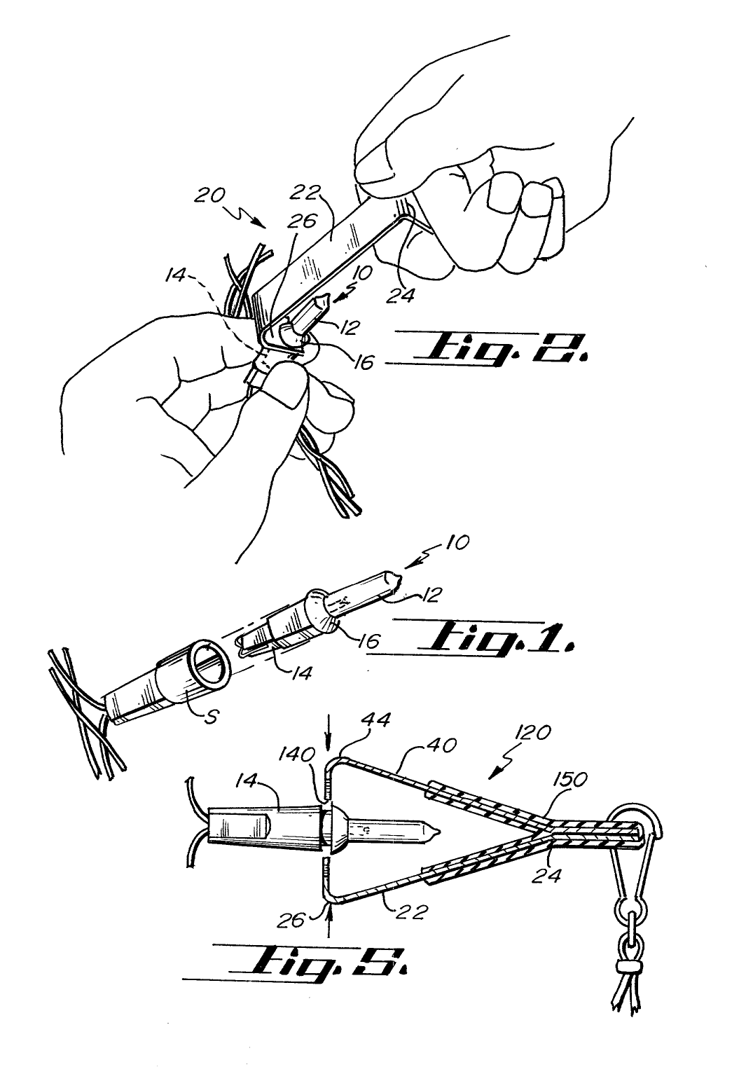

FIG. 1 is a drawing of a type 2.5vSB midget push-in lamp. The lamp 10 comprises a glass element 12, a base 14, and a circular collar 16 between the glass element 12 and the base 14.

The present invention is particularly designed to extract type 2.5vSB midget push-in lamps 10 from sockets, but can also be used with a variety of different lamp types. The collar 16 of the type 2.5vSB lamp has a diameter of approximately 8 mm.

The present invention is an apparatus 20 for extracting and installing light bulbs from sockets S.

In one embodiment, (FIGS. 2-4), the apparatus 20 comprises a first handle 22 having a first end 24 and a second end 26 and a groove 28 in the second end 26. As seen in the Figures, the groove 28 is adapted to securely grip the base 14 adjacent the collar 16, thereby allowing the operator to extract the bulb 10 from the socket and insert another bulb 10 in the socket S.

The apparatus 20 may also further comprise a rubberized layer 30 on the first handle 22 for insulating the operator's fingers from the handle 22.

The apparatus 22 may also further comprise an aperture 32 in the first end 24 and a lanyard 34 connected to the aperture 22, thereby allowing the operator to hang the apparatus about the neck by the lanyard 34.

To provide the best leverage, the second end 26 is preferably bent substantially perpendicular to the first handle 22, as seen in the Figure.

To remove a light bulb 10 from a socket S, the operator inserts the groove 28 around the base 14 adjacent the collar 16, then pulls the bulb 10 out of the socket S while gripping the socket S in the other hand. Because the second end 26 is preferably bent substantially perpendicular to the first handle 22, the operator may grip the first handle 22 in one hand and remove the bulb by simply moving his hands apart, as shown by the arrows in the Figure.

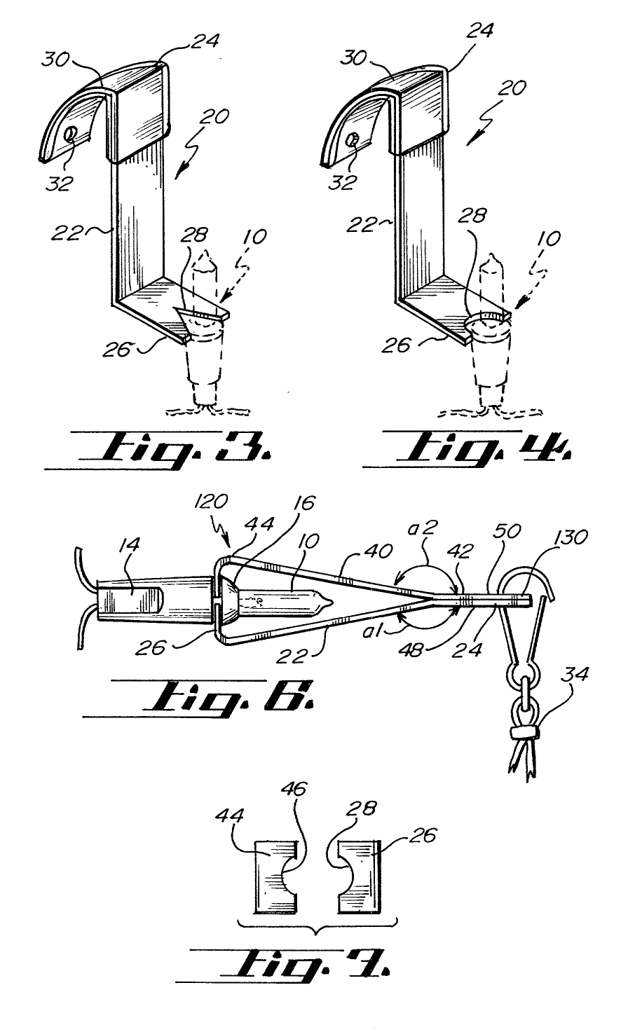

FIGS. 3 and 4 show that the first end 24 may preferably be curved in order to allow gripping by the operator's finger. Also, the groove 28 may be either V-shaped (FIG. 3) or substantially semicircular (FIG. 4.)

A second embodiment of the invention is shown in FIGS. 5-7.

In the second embodiment, the apparatus 120, in addition to the features discussed above, further comprises a second handle 40 having a first end 42 and a second end 44 and a groove 46 at the second end 44. As best seen in FIGS. 5 and 6, the second end 26 of the first handle 22 and the second end 44 of the second handle 40 are adjustably spaced from one another for receiving light bulb bases 14 of varying sizes. The second ends 26, 44 are also opposable for gripping the light bulb base 14 therebetween, thereby allowing the operator to extract the light bulb and insert another light bulb in the socket S.

Preferably, the second ends 26, 44 are bent substantially perpendicular to the handles 22, 40.

In the preferred embodiment, the first ends 24, 42 are joined at substantially flat portions 48,50 and the flat portions 48, 50 lie at obtuse angles a₁, a₂ to the axes of the handles 22, 40.

Preferably, the apparatus 120 also comprises a spring means 130 urging the second ends 26, 44 apart, thereby forming a gap 140 adapted to receive the light bulb 10. Most preferably, the handles 22, 40 are metal and the spring means 130 further comprises the innate spring tension resulting from the first ends 24, 42 being joined at the substantially flat portions 48, 50 while the handle axes are angled away from the flat portions 48,50. In addition, a rubberized material 150 may encase the joined flat portions 48,50 and assist the innate spring tension in urging the second ends 26, 44 apart.

Operation of the second embodiment is seen in FIGS. 5 and 6. FIG. 5 shows the apparatus 120 being positioned over the bulb 10 so that the spaced apart second ends 26, 44 encompass but do not touch the base 14, which is in the gap 140. Next, the operator squeezes the second ends 26, 44 together as shown by the arrows, so that the second ends 26, 44 oppose one another, as shown in FIG. 6, and grip the base 14 of the bulb 10 adjacent the collar 16. With the bulb 10 thus gripped between the second ends 26, 44, the bulb may be extracted from the socket. A new bulb may then be gripped between the second ends 26, 44 and inserted in the socket by reversing the above procedure. Because of the firm grip provided on the base 14 by the opposed second ends 26, 44, the bulb will not come loose from the apparatus 120 as the bulb encounters frictional resistance with the socket.

It will be recognized that the variable spacing of the second ends 26, 44 will allow the apparatus 120 to be used with bulbs having various base and collar diameters, or no collar at all.

The present invention may be embodied in other specific forms without departing from the spirit or essential attributes thereof, and it is therefore desired that the present embodiment be considered in all respects as illustrative and not restrictive, reference being made to the appended claims rather than to the foregoing description to indicate the scope of the invention.

What is claimed:

1. Apparatus for extracting and installing light bulbs from sockets, the light bulbs having a glass element, a base, and a circular collar between the glass element and the base, the base being insertable into a socket, the apparatus comprising:
a) a first handle having a first end and a second end and a longitudinal axis between the first end and the second end, wherein the second end is bent substantially perpendicular to the longitudinal axis; and
b) a groove in the second end adapted to securely grip the base adjacent the collar of the light bulb, thereby allowing the operator to extract the light bulb and insert another light bulb into the socket.

2. The apparatus of claim 1, further comprising a rubberized layer on the first handle for insulating the operator's fingers from the handle.

3. The apparatus of claim 1, further comprising an aperture in the first end and a lanyard connected to the aperture, whereby the apparatus may be hung about the operator's neck.

4. The apparatus of claim 1, further comprising a second handle having a first end and a second end and a groove at the second end, the second end of the first handle and the second end of the second handle being adjustably spaced from one another for receiving light bulb bases of varying size.

5. The apparatus of claim 4, wherein the first end of the first handle and the first end of the second handle are joined at substantially flat portions lying at an obtuse angle to the axes of the first handle and second handle.

6. The apparatus of claim 5, further comprising a spring means urging the second end of the first handle to separate from the second end of the second handle, thereby forming a gap adapted to receive the light bulb's base.

7. The apparatus of claim 6, wherein the first handle and the second handle are metal and wherein the spring means further comprises the innate spring tension resulting from the first handle being joined to the second handle at the substantially flat portions.

8. The apparatus of claim 7, further comprising a rubberized material encasing the joined substantially flat portions and assisting the innate spring tension in urging the second end of the first handle to separate from the second end of the second handle.

9. Apparatus for extracting and installing light bulbs from sockets, the light bulbs having a glass element, a base, and a circular collar between the glass element and the base, the base being insertable into a socket, the apparatus comprising:
a) a first handle having a first end and a second end and a groove in the second end adapted to securely grip the base adjacent the collar of the light bulb; and
b) a second handle having a first end and a second end and a groove at the second end, the second end of the first handle and the second end of the second handle being adjustably spaced from one another for receiving light bulb bases of varying size and being opposable for gripping the light bulb base therebetween, thereby allowing the operator to extract the light bulb and insert another light bulb into the socket.

10. The apparatus of claim 9, further comprising an aperture in the first ends and a lanyard connected to the aperture, whereby the apparatus may be hung about the operator's neck.

11. The apparatus of claim 9, wherein the second ends are bent substantially perpendicular to the handles.

12. The apparatus of claim 9, wherein the first end of the first handle and the first end of the second handle are joined at substantially flat portions lying at an obtuse angle to the axes of the first handle and second handle.

13. The apparatus of claim 12, further comprising a spring means urging the second end of the first handle to separate from the second end of the second handle, thereby forming a gap adapted to receive the light bulb's base.

14. The apparatus of claim 13, wherein the first handle and the second handle are metal and wherein the spring means further comprises the innate spring tension resulting from the first handle being joined to the second handle at the substantially flat portions.

15. The apparatus of claim 14, further comprising a rubberized material encasing the joined substantially flat portions and assisting the innate spring tension in urging the second end of the first handle to separate from the second end of the second handle.

16. Apparatus for extracting and installing light bulbs from sockets, the light bulbs having a glass element, a base, and a circular collar between the glass element and the base, the base being insertable into a socket, the apparatus comprising:
a) a first handle having a first end and a second end and a groove in the second end adapted to securely grip the base adjacent the collar of the light bulb;
b) a second handle having a first end and a second end and a groove at the second end, the second end of the first handle and the second end of the second handle being adjustably spaced from one another for receiving light bulb bases of varying size and being opposable for gripping the light bulb base therebetween, thereby allowing the operator to extract the light bulb and insert another light bulb into the socket; and
c) a spring means urging the second end of the first handle to separate from the second end of the second handle, thereby forming a gap adapted to receive the light bulb's base.

17. The apparatus of claim 16, wherein the first end of the first handle and the first end of the second handle are joined at substantially flat portions lying at an obtuse angle to the axes of the first handle and second handle.

18. The apparatus of claim 17, further comprising a spring means urging the second end of the first handle to separate from the second end of the second handle, thereby forming a gap adapted to receive the light bulb's base.

19. The apparatus of claim 18, wherein the first handle and the second handle are metal and wherein the spring means further comprises the innate spring tension resulting from the first handle being joined to the second handle at the substantially flat portions.

20. The apparatus of claim 19, further comprising a rubberized material encasing the joined substantially flat portions and assisting the innate spring tension in urging the second end of the first handle to separate from the second end of the second handle.
